(19) United States
(12) Patent Application Publication
(10) Pub. No.: US 2013/0307001 A1
(43) Pub. Date: Nov. 21, 2013

(54) n-AlGaN THIN FILM AND ULTRAVIOLET LIGHT EMITTING DEVICE INCLUDING THE SAME

(71) Applicant: SAMSUNG ELECTRONICS CO., LTD., Gyeonggi-do (KR)

(72) Inventors: Jin-sub Lee, Gyeonggi-do (KR); Jung-sub Kim, Hwaseong-Si (KR); Cheol-soo Sone, Seoul (KR)

(73) Assignee: SAMSUNG ELECTRONICS CO., LTD., Gyeonggi-do (KR)

(21) Appl. No.: 13/844,730

(22) Filed: Mar. 15, 2013

(30) Foreign Application Priority Data
May 18, 2012 (KR) 10-2012-0053152

(51) Int. Cl. H01L 33/12

(52) U.S. Cl. CPC H01L 33/12
USPC 257/94; 257/190

(57) ABSTRACT

An n-type aluminum gallium nitride (AlGaN) thin film and an ultraviolet light emitting device including the same. The ultraviolet light emitting device includes: an aluminum nitride (AlN) buffer layer on a substrate; and an n-type AlGaN layer, an active layer, a p-type AlGaN layer that are sequentially stacked on the AlN buffer layer. A silicon doping density of the n-type AlGaN layer increases with respect to an increasing vertical position of the n-AlGaN layer with reference to the AlN buffer layer.

### CROSS-REFERENCE TO RELATED APPLICATION

This application claims the benefit of priority to Korean Patent Application No. 10-2012-0053152, filed on May 18, 2012, in the Korean Intellectual Property Office, the disclosure of which is incorporated herein in its entirety by reference.

1. Field

The present disclosure relates to aluminum gallium nitride (AlGaN) thin films, of which density of n-type impurities varies sequentially, and ultraviolet light emitting devices including the thin films.

2. Background

A light emitting device converts a current into light, and the wavelength of emitted light varies according to the semiconductor material included in the light emitting device. In other words, the wavelength of emitted light varies according to the band-gaps of semiconductor materials, that is, the energy differences between electrons of a valence band and electrons of a conduction band.

An ultraviolet light emitting device emits ultraviolet light. To emit ultraviolet light, n-aluminum gallium nitride (AlGaN), AlGaN, and p-AlGaN may be respectively used to form an n-type semiconductor layer, an active layer, and a p-type semiconductor layer of the light emitting device.

An aluminum nitride (AlN) buffer layer is formed on a substrate in order to form an n-AlGaN layer. However, due to tensile stress caused by a difference in the lattice constants between the AlGaN layer and the AlN buffer layer, cracks may be formed in the AlGaN layer. More cracks may be formed when silicon, which is an n-type impurity, is doped in the AlGaN layer and a doping density thereof increases.

### SUMMARY

Provided are ultraviolet light emitting devices in which a doping density of silicon increases sequentially in order to suppress the formation of cracks in an n-type aluminum gallium nitride (AlGaN) layer.

Additional aspects will be set forth in part in the description which follows and, in part, will be apparent from the description, or may be learned by practice of the presented embodiments.

According to an aspect of the present disclosure, there is provided an n-type aluminum gallium nitride (AlGaN) thin film on an aluminum nitride (AlN) buffer layer, wherein a silicon doping density of the n-type AlGaN layer increases with respect to an increasing vertical position of the n-type AlGaN layer with reference to the AlN buffer layer.

The n-type AlGaN layer may have a thickness of about 2 μm to about 4 μm.

The silicon doping density of the n-AlGaN layer may gradually increase from a first doping density, to a second doping density, which is higher than the first doping density.

The n-type AlGaN layer may comprise a first layer that is disposed directly on the AlN buffer layer and has a first doping density, a second layer that is disposed on the first layer and has a silicon doping density that increases gradually from the first doping density to a second doping density, and a third layer that is disposed on the second layer and has the second doping density.

The n-type AlGaN layer may comprise at least four stacked layers, a lowermost layer formed directly on the AlN buffer layer having a first doping density, and an uppermost layer having a second density which is higher than the first silicon doping density, and silicon doping densities of layers between the lowermost and uppermost layers sequentially increase between the first doping density and the second doping density.

The first doping density may be substantially equal to 5×10¹⁸ atoms/cm³, and the second doping density may be substantially equal to 5×10¹⁹ atoms/cm³.

According to another aspect, an ultraviolet light emitting device includes: an aluminum nitride (AlN) buffer layer disposed on a substrate; and an n-type AlGaN layer, an active layer, a p-type AlGaN layer that are sequentially stacked on the AlN buffer layer, wherein a silicon doping density of the n-type AlGaN layer increases with respect to an increasing vertical position of the n-type AlGaN layer with reference to the AlN buffer layer.

According to an aspect of the present disclosure, a light emitting device comprises an aluminum nitride (AlN) buffer layer disposed on a substrate; and in sequential stacked order from the AlN buffer layer an n-type AlGaN multilayer, an active layer, and a p-type AlGaN layer. The silicon doping density of each layer of said n-type AlGaN multilayer increases with distance from said AlN buffer layer.

### BRIEF DESCRIPTION OF THE DRAWINGS

FIG. 1 is a cross-sectional view illustrating an ultraviolet light emitting device according to an embodiment of the present disclosure;

FIG. 2 is a graph showing a silicon (Si) doping density according to vertical positions of an n-aluminum gallium nitride (AlGaN) layer according to an embodiment of the present disclosure;

FIG. 3 is a cross-sectional view illustrating an n-AlGaN layer according to another embodiment of the present disclosure;

FIG. 4 is a graph showing a Si doping density according to vertical positions of an n-AlGaN layer according to another embodiment of the present disclosure; and

FIG. 5 is a cross-sectional view illustrating an n-AlGaN layer according to another embodiment of the present disclosure.

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description. The sizes or thicknesses of elements may be exaggerated for clarity of description. It will also be understood that when a layer is referred to as being “on” another layer or substrate, it can be directly on the other layer, or intervening layers may also be present.

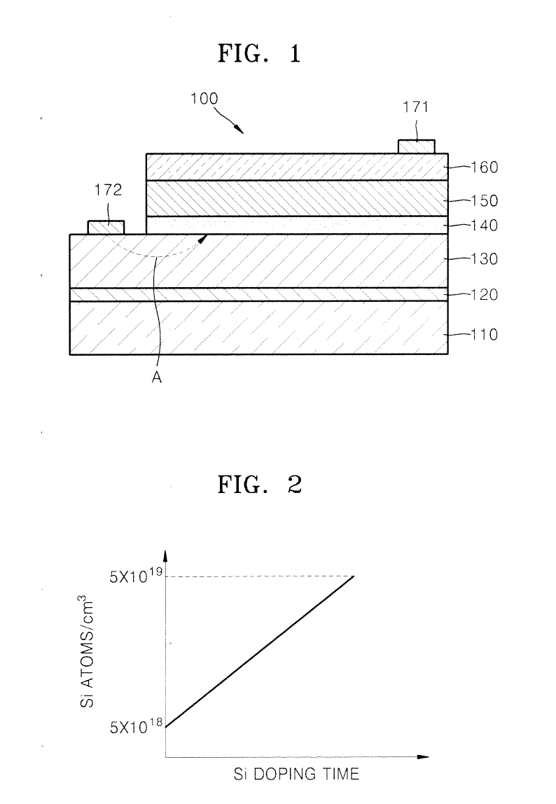

FIG. 1 is a cross-sectional view illustrating an ultraviolet light emitting device 100 including an n-type aluminum gallium nitride (AlGaN) thin film according to an embodiment of the present disclosure.

Referring to FIG. 1, a buffer layer 120, an n-type semiconductor layer 130, an active layer 140, and a p-type semiconductor layer 150 are sequentially stacked on a substrate 110. When a forward bias is applied to the ultraviolet light emitting device 100, electrons of the n-type semiconductor layer 130 and holes of the p-type semiconductor layer 150 are recombined with each other, and light is emitted from the active layer 140.

A light emitting device may generate light of different wavelengths according to the types and materials of respective layers of the light emitting device. In order to allow deep ultraviolet light (DUV) having a wavelength of about 100 nm to about 350 nm, particularly, from about 100 nm to about 290 nm, to be emitted from the active layer 140, the n-type semiconductor layer 130 and the p-type semiconductor layer 150 may be formed of AlGaN compound semiconductors. That is, the n-type semiconductor layer 130 includes an n-type AlGaN layer, and the p-type semiconductor layer 150 includes a p-type AlGaN layer, and the active layer 140 may include an undoped AlGaN layer.

The substrate 110 may be a substrate for monocrystalline semiconductor growth, and may be formed of, for example, sapphire.

The buffer layer 120 is a layer for minimizing a lattice difference in between the substrate 110, for example, a sapphire substrate, and the n-type semiconductor layer 130 to be formed on the substrate 110. The buffer layer 120 may be formed of AlN.

In order that ultraviolet rays are generated from the active layer 140, the n-type semiconductor layer 130 may be formed by doping a semiconductor material including AlGaN, with an n-type impurity. The n-type impurity may be a Group IV element, for example, silicon (Si). The n-type semiconductor layer 130 may be formed by using, for example, a metal-organic chemical vapor deposition (MOCVD) method, a hydride vapor phase epitaxy (HVPE) method, or a molecular beam epitaxy (MBE) method. The n-type semiconductor layer 130 may have a thickness of about 2 μm to about 4 μm.

An n-type electrode 172 is formed on the n-type semiconductor layer 130 to supply power thereto.

In order that ultraviolet rays are generated from the active layer 140, the p-type semiconductor layer 150 may be formed by doping a semiconductor material including AlGaN with a p-type impurity. The p-type impurity may be a Group II element, for example, Mg, Zn, or Be. The p-type semiconductor layer 150 may be formed by using, for example, a MOCVD method, a HVPE method, or a MBE method.

A p-contact layer 160 may be further formed on the p-type semiconductor layer 150. The p-contact layer 160 may be formed of p-GaN. The p-AlGaN layer 150 has greater activation energy than GaN not including Al. Accordingly, even when p-type impurities are implanted into AlGaN, a doping density thereof is lower than that of GaN. The doping density of the p-type semiconductor layer 150 decreases with the Al content. Accordingly, the p-contact layer 160 may be disposed between the p-type semiconductor layer 150 and a p-type electrode 171.

The p-type electrode 171 is formed on the p-contact layer 160 to supply power thereto.

The active layer 140 emits light having a predetermined energy by recombination of electrons and holes that are respectively injected from the n-type electrode 172 and the p-type electrode 171. The active layer 140 may have a structure in which a quantum well layer and a quantum barrier layer are alternately stacked at least once. The quantum well layer may have a single quantum well structure or a multi-quantum well structure.

The n-AlGaN layer 130 may be doped with Si. When the n-AlGaN layer 130 is simply grown on the AlN buffer layer 120, due to a lattice constant difference between the AlN buffer layer 120 and the n-AlGaN layer 130, cracks may be formed in the n-AlGaN layer 130. In particular, when a doping density of Si increases, more cracks may be formed.

The n-AlGaN layer 130 may have a Si doping density that is not uniform but varies at a predetermined rate.

FIG. 2 is a graph showing a doping density of Si according to vertical positions of an n-AlGaN layer 130 according to an embodiment of the present disclosure.

Referring to FIG. 2, the doping density of Si in the n-AlGaN layer 130 from the buffer layer 120 increases sequentially from a first density of 5×10¹⁸ atoms/cm³ to a second density of 5×10¹⁹ atoms/cm³. By sequentially increasing the doping density of Si, the effect due to high-density silicon doping is reduced, and less cracks are formed in the n-AlGaN layer 130. The doping density of Si may be increased by sequentially increasing an amount of a Si source, for example, silane gas into a chamber.

The first density is not limited to 5×10¹⁸ atoms/cm³, and may be of the order of 10¹⁸ atoms/cm³. The second density is not limited to 5×10¹⁹ atoms/cm³, and may be of the order of 10¹⁹ atoms/cm³.

Electrons are injected from the n-type electrode 172 to the n-AlGaN layer 130 mainly on the n-AlGaN layer 130 in areas where the doping density of the n-AlGaN layer 130 is high, as shown by an electron injection path denoted by an arrow A in FIG. 1, thus the injection of the electrons may be easily performed.

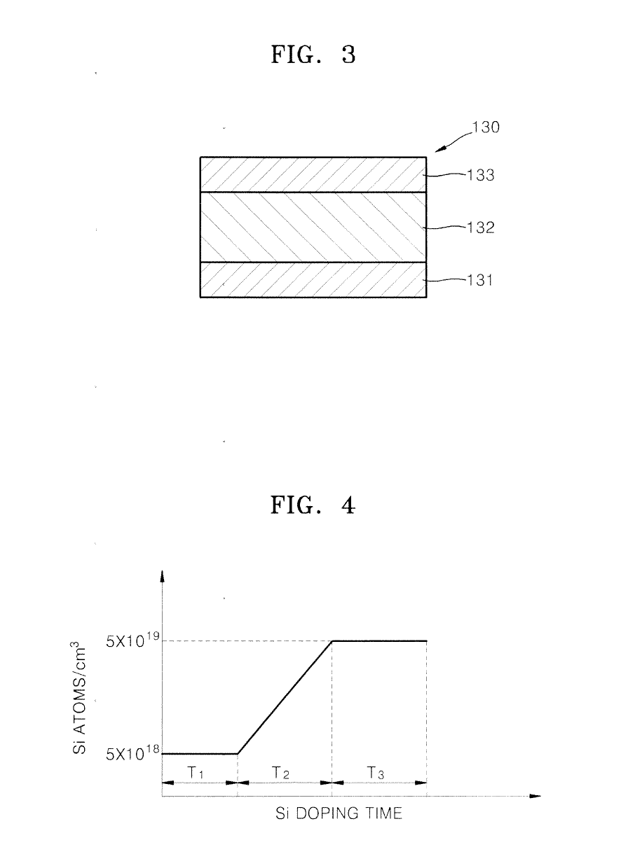

FIG. 3 is a cross-sectional view illustrating an n-AlGaN layer 130 according to another embodiment, and FIG. 4 is a graph showing a doping density of Si according to vertical positions of the n-AlGaN layer 130 according to another embodiment.

Referring to FIGS. 3 and 4, the n-AlGaN layer 130 may include a first layer 131 that is directly formed on an AlN buffer layer 120 and a second layer 132 and a third layer 133 that are sequentially stacked on the first layer 131. The first layer 131 is an n-AlGaN layer having a uniform Si doping density of 5×10¹⁸ atoms/cm³. Referring to FIG. 4, a silicon source is uniformly supplied during a first duration T1.

The second layer 132 has a Si doping density that sequentially increases from 5×10¹⁸ atoms/cm³ to 5×10¹⁹ atoms/cm³ from the first layer 131. Referring to FIG. 4, supply of a silicon source during a second duration T2 is increased at a uniform rate.

The third layer 133 is an n-AlGaN layer having a silicon doping density of 5×10¹⁹ atoms/cm³. Referring to FIG. 4, the supply from the silicon source is uniformly maintained during a third duration T3. The effect due to lattice constant between highly doped n-AlGaN layer and the AlN buffer layer 120 is reduced, and accordingly, formation of cracks in the n-AlGaN layer 130 is reduced. A sequential adjustment of the doping density of Si may be performed by sequentially increasing an amount of a silicon source into a chamber, for example, silane gas.

Meanwhile, electrons are injected from the n-type electrode 172 to the n-AlGaN layer 130 mainly in the third layer 133 of the n-AlGaN layer 130 which is a highly doped area, as shown by the arrow A of FIG. 1.

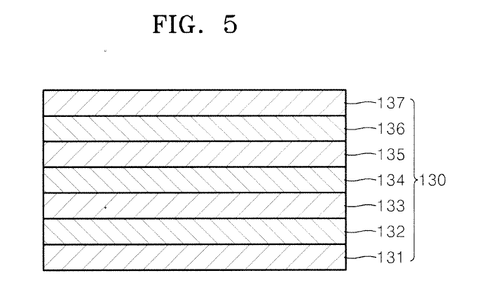

FIG. 5 is a cross-sectional view illustrating an n-AlGaN layer 130 according to another embodiment of the present disclosure.

Referring to FIG. 5, the n-AlGaN layer 130 includes a plurality of layers. From an example of FIG. 3, the n-AlGaN layer 130 includes seven layers from a lowermost layer 131 from the buffer layer 120 (refer to FIG. 1) to an uppermost layer 137. The lowermost layer 131 may have a silicon doping density of 5×10¹⁸ atoms/cm³, and a doping density of the layers 132 through 137 may gradually increase upwardly, and the uppermost layer 137 may have a silicon doping density of 5×10¹⁹ atoms/cm³. Accordingly, the effect due to lattice constant between highly silicon doped n-AlGaN layer and the AlN buffer layer 120 is reduced, and thus, formation of cracks in the n-AlGaN layer 130 is reduced.

In addition, electrons are injected from the n-type electrode 172 to the n-AlGaN layer 130 mainly on the n-AlGaN layer 130 in a highly doped area of the n-AlGaN layer 130. Thus, electrons may be easily injected.

According to an n-type AlGaN thin film in a ultraviolet light emitting device according to the embodiments of the present disclosure, as an impurity density in the n-type AlGaN thin film sequentially increases from a buffer layer, formation of cracks due to high-density impurities may be reduced.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. An n-type aluminum gallium nitride (AlGaN) thin film on an aluminum nitride (AlN) buffer layer,
wherein a silicon doping density of the n-type AlGaN layer increases with respect to an increasing vertical position of the n-type AlGaN layer with reference to the AlN buffer layer.

2. The N-type AlGaN thin film of claim 1, wherein the n-type AlGaN layer has a thickness of about 2 μm to about 4 μm.

3. The N-type AlGaN thin film of claim 1, wherein the silicon doping density of the n-type AlGaN layer gradually increases from a first doping density, to a second doping density.

4. The n-type AlGaN thin film of claim 1, wherein the n-type AlGaN layer comprises a first layer that is disposed directly on the AlN buffer layer and has a first doping density, a second layer that is disposed on the first layer and has a silicon doping density that increases gradually from the first doping density to a second doping density, and a third layer that is disposed on the second layer and has the second doping density.

5. the n-type AlGaN thin film of claim 1, wherein the n-type AlGaN layer comprises:
at least four stacked layers,
a lowermost layer disposed directly on the AlN buffer layer and having a first doping density, and
an uppermost layer having a second density which is higher than the first silicon doping density, wherein silicon doping densities of the stacked layers between the lowermost and uppermost layers sequentially increase between the first doping density and the second doping density.

6. The n-type AlGaN thin film of claim 3, wherein the first doping density is of the order of 10¹⁸ atoms/cm³, and the second density is of the order of 10¹⁹ atoms/cm³.

7. The n-type AlGaN thin film of claim 6, wherein the first doping density is substantially equal to 5×10¹⁸ atoms/cm³, and the second doping density is substantially equal to 5×10¹⁹ atoms/cm³.

8. An ultraviolet light emitting device comprising:
an aluminum nitride (AlN) buffer layer disposed on a substrate; and
an n-type AlGaN layer, an active layer, and a p-type AlGaN layer that are sequentially stacked on the AlN buffer layer,
wherein a silicon doping density of the n-type AlGaN layer increases with respect to an increasing vertical position of the n-type AlGaN layer with reference to the AlN buffer layer.

9. The ultraviolet light emitting device of claim 8, wherein the n-AlGaN layer has a thickness of about 2 μm to about 4 μm.

10. The ultraviolet light emitting device of claim 8, wherein the silicon doping density of the n-type AlGaN layer gradually increases from a first doping density, to a second doping density which is higher than the first doping density.

11. The ultraviolet light emitting device of claim 8, wherein the n-type AlGaN layer comprises a first layer that is disposed directly on the AlN buffer layer and has a first doping density, a second layer that is disposed on the first layer and has a silicon doping density that increases gradually from the first doping density to a second doping density, and a third layer that is disposed on the second layer and has the second doping density.

12. The ultraviolet light emitting device of claim 8, wherein the n-type AlGaN layer comprises:
at least four stacked layers,
a lowermost layer disposed directly on the AlN buffer layer and having a first doping density, and
an uppermost layer having a second density which is higher than the first density, wherein silicon doping densities of the stacked layers between the lowermost layer and the uppermost layer sequentially increase between the first doping density and the second doping density.

13. The ultraviolet light emitting device of claim 10, wherein the first doping density is of the order of 10¹⁸ atoms/cm³, and the second doping density is of the order of 10¹⁹ atoms/cm³.

14. The ultraviolet light emitting device of claim 13, wherein the first doping density is substantially equal to 5×10¹⁸ atoms/cm³, and the second doping density is substantially equal to 5×10¹⁹ atoms/cm³.

15. A light emitting device comprising:
an aluminum nitride (AlN) buffer layer disposed on a substrate; and
in sequential stacked order from said AlN buffer layer: an n-type AlGaN multilayer, an active layer, and a p-type AlGaN layer,
wherein a silicon doping density of each layer of said n-type AlGaN multilayer increases with distance from said AlN buffer layer.

16. The light emitting device of claim 15, wherein the n-type AlGaN multilayer has a thickness of about 2 μm to about 4 μm.

17. The light emitting device of claim 15, wherein the n-AlGaN multilayer comprises a first layer that is disposed directly on the AlN buffer layer and has a first doping density, a second layer that is disposed on the first layer and has a silicon doping density that increases gradually from the first doping density to a second doping density, and a third layer that is disposed on the second layer and has the second doping density.

18. The light emitting device of claim 15, wherein the n-type AlGaN multilayer comprises at least four stacked layers, and a lowermost layer formed directly on the AlN buffer layer has a low doping density, and an uppermost layer having a high silicon doping density, and silicon doping densities of layers between the lowermost layer and the uppermost layer sequentially increase between the low doping density and the high doping density.

19. The light emitting device of claim 18, wherein the low doping density is of the order of 10¹⁸ atoms/cm³, and the high doping density is of the order of 10¹⁹ atoms/cm³.

20. The light emitting device of claim 19, wherein the low doping density is substantially equal to 5×10¹⁸ atoms/cm³, and the high doping density is substantially equal to 5×10¹⁹ atoms/cm³.
